(19) United States
(12) Patent Application Publication
(10) Pub. No.: US 2026/0033266 A1
(43) Pub. Date: Jan. 29, 2026

(54) METHOD OF MANUFACTURING LAMINATED WAFER WITH PROCESSED OUTER CIRCUMFERENCE, METHOD OF MANUFACTURING DEVICE CHIPS, AND APPARATUS FOR PROCESSING LAMINATED WAFER

(71) Applicant: DISCO CORPORATION, Tokyo (JP)

(72) Inventors: Kokichi MINATO, Tokyo (JP); Atsushi KOMATSU, Tokyo (JP)

(21) Appl. No.: 19/282,458

(22) Filed: Jul. 28, 2025

(30) Foreign Application Priority Data
Jul. 29, 2024 (JP) 2024-122125
Sep. 24, 2024 (JP) 2024-165461
May 19, 2025 (JP) 2025-083256

(51) Int. Cl. H01L 21/463; B24B 37/005; B24B 51/00; H01L 21/683; H01L 21/78

(52) U.S. Cl. CPC H01L 21/463; B24B 37/005; B24B 51/00; H01L 21/6836; H01L 21/78; H01L 2221/68327

(57) ABSTRACT

A method of manufacturing a laminated wafer with a processed outer circumference includes acquiring a value of joint misalignment between a first wafer and a second wafer of the laminated wafer by measuring the positions of outer circumferences of the first and second wafers, holding the second wafer of the laminated wafer on a holding surface of a holding mechanism, acquiring the position of the first wafer with respect to the holding mechanism while the laminated wafer is being held by the holding mechanism, acquiring the position of the second wafer with respect to the holding mechanism on the basis of the acquired value of joint misalignment and the acquired position of the first wafer, and processing the outer circumference of the first wafer on the basis of the acquired position of the second wafer as a reference.

### BACKGROUND OF THE INVENTION

### Field of the Invention

The present invention relates to a method of manufacturing a laminated wafer including a first wafer and a second wafer layered on the first wafer and having a processed outer circumference, a method of manufacturing device chips from a laminated wafer, and an apparatus for processing the outer circumference of a laminated wafer.

### Description of the Related Art

Device chips to be incorporated in electronic appliances such as cellular phones and personal computers, for example, are manufactured by processing semiconductor wafers.

A disk-shaped semiconductor wafer has a grid of projected dicing lines also known as streets established on one surface thereof and a plurality of devices such as integrated circuits (ICs) or large-scale-integration (LSI) circuits constructed in respective rectangular areas demarcated in the wafer by the projected dicing lines. The semiconductor wafer with the devices thereon is divided into a plurality of device chips when it is cut along the projected dicing lines.

In recent years, it has been customary to thin down wafers in order to make device chips smaller in size and weight before the wafers are divided into the device chips. Specifically, in the above process of manufacturing device chips from a wafer, for example, the wafer with devices on its face side has its reverse side ground so that the wafer will be thinned down in its entirety.

Sometimes, a laminated wafer that includes a wafer to be processed, also referred to as a first wafer, and another wafer, also referred to as a second wafer, joined as a support substrate to the first wafer, is used to keep a desired level of mechanical strength after the first wafer has been thinned down. While the first wafer joined to the second wafer is being thinned down by being ground, the laminated wafer remains thick enough on account of the second wafer to keep its mechanical strength as a whole.

In order to prevent wafers from chipping at their outer circumferential edges when the wafers are handled, e.g., delivered and processed, the outer circumferential edges are often beveled. When a wafer with a beveled outer circumferential edge is thinned down by being ground, the beveled outer circumferential edge is turned into a thinner sharp edge called a knife edge.

Since the knife edge of the thinned-down wafer is more likely to produce fragments or chippings, it is the usual practice to perform an edge trimming process to remove the beveled edge immediately before the wafer is ground. Specifically, for example, a cutting blade is caused to cut into the beveled outer circumferential edge of the wafer while moving therealong, thereby removing the beveled edge.

Japanese Patent Laid-open No. 2000-173961, for example, discloses a technology regarding the wafer edge trimming process.

A laminated wafer including a first wafer and a second wafer joined to each other may have the first wafer processed by the edge trimming process. When the first wafer and the second wafer are joined to each other, their centers may be positionally misaligned with each other. If the first and second wafers that are equal in diameter to each other are joined while their centers are positionally misaligned with each other, then a portion of the outer circumference of the first wafer protrudes radially outwardly from the outer circumference of the second wafer.

When the outer circumference of the first wafer is then cut across a certain width, for example, the portion of the outer circumference of the first wafer remains protruding radially outwardly from the outer circumference of the second wafer and is left unjoined to the second wafer, depending on the width across which the outer circumference of the first wafer is cut and the distance by which the centers of the first and second wafers are misaligned with each other.

If the first wafer of the laminated wafer thus processed is then processed, e.g., ground or cut, then the portion of the outer circumference of the first wafer that is not joined to the second wafer is processed without being supported by the second wafer. As a result, the portion of the outer circumference of the first wafer that is not joined to the second wafer and other nearby portions of the first wafer may possibly tend to chip or crack.

### SUMMARY OF THE INVENTION

It is therefore an object of the present invention to provide a method of manufacturing a laminated wafer including a first wafer and a second wafer layered on the first wafer and having a processed outer circumference, a method of manufacturing device chips from a laminated wafer, and an apparatus for processing the outer circumference of a laminated wafer, that are capable of appropriately processing the outer circumference of the laminated wafer even if the first and second wafers are joined to each other while being positionally misaligned with each other.

In accordance with an aspect of the present invention, there is provided a method of manufacturing a laminated wafer with a processed outer circumference from a laminated wafer including a first wafer and a second wafer that are each plate-shaped and have respective surfaces joined to each other, by processing an outer circumference of the first wafer, the method including acquiring a value of joint misalignment between the first wafer and the second wafer by measuring a position of the outer circumference of the first wafer and a position of an outer circumference of the second wafer, holding the second wafer of the laminated wafer on a holding surface of a holding mechanism, acquiring a position of the first wafer with respect to the holding mechanism while the laminated wafer is being held by the holding mechanism, acquiring a position of the second wafer with respect to the holding mechanism on the basis of the acquired value of the joint misalignment and the acquired position of the first wafer, and processing the outer circumference of the first wafer on the basis of the acquired position of the second wafer as a reference.

According to the aspect of the present invention, preferably, the method uses a processing apparatus including the holding mechanism that is rotatable about a rotational axis extending transversely to the holding surface, and a cutting blade for cutting into the laminated wafer held by the holding mechanism, the method further including acquiring a value of misalignment between a position of a rotational axis of the holding mechanism and a position of the center of the second wafer held by the holding mechanism, in which the outer circumference of the first wafer is cut by rotating the holding mechanism together with the laminated wafer held by the holding mechanism, and cutting the outer circumference of the first wafer while adjusting a position of the cutting blade with respect to the holding mechanism depending on an angle of the holding mechanism on the basis of the value of misalignment between the position of the rotational axis of the holding mechanism and the position of the center of the second wafer held by the holding mechanism.

In accordance with another aspect of the present invention, there is provided a processing apparatus for processing a laminated wafer including a first wafer and a second wafer that are each plate-shaped and have respective surfaces joined to each other, the processing apparatus including a first holding mechanism for holding a target, a detector for detecting a position of an outer circumference of the target held by the first holding mechanism at a position spaced radially outwardly from the target, a cutting blade for cutting into the target held by a second holding mechanism, and a controller for adjusting a relative positional relation between the second holding mechanism and the cutting blade.

According to the other aspect of the present invention, the first holding mechanism and the second holding mechanism preferably are the same holding mechanism.

In accordance with a further aspect of the present invention, there is provided a method of manufacturing device chips using the method of manufacturing a laminated wafer with a processed outer circumference from a laminated wafer including a first wafer and a second wafer that are each plate-shaped and have respective surfaces joined to each other, by processing an outer circumference of the first wafer, the method including acquiring a value of joint misalignment between the first wafer and the second wafer by measuring a position of the outer circumference of the first wafer and a position of an outer circumference of the second wafer, holding the second wafer of the laminated wafer on a holding surface of a holding mechanism, acquiring a position of the first wafer with respect to the holding mechanism while the laminated wafer is being held by the holding mechanism, acquiring a position of the second wafer with respect to the holding mechanism on a basis of the acquired value of the joint misalignment and the acquired position of the first wafer, and processing the outer circumference of the first wafer on a basis of the acquired position of the second wafer as a reference, the method further including, after the outer circumference of the first wafer has been processed, dividing the first wafer into device chips.

With the methods of manufacturing a laminated wafer with a processed outer circumference and the method of manufacturing device chips according to the aspects of the present invention, the outer circumference of the first wafer is processed on the basis of the position of the center of the second wafer as a reference.

With the processing apparatus for processing a laminated wafer according to the other aspect of the present invention, the position of the second wafer is acquired by the detector spaced radially outwardly from the laminated wafer as the target.

The method of manufacturing a laminated wafer with a processed outer circumference, the method of manufacturing device chips, and the processing apparatus for processing a laminated wafer according to the present invention are thus able to appropriately process the outer circumference of the laminated wafer even if joint misalignment occurs between the first wafer and the second wafer.

The above and other objects, features and advantages of the present invention and the manner of realizing them will become more apparent, and the invention itself will best be understood from a study of the following description and appended claims with reference to the attached drawings showing a preferred embodiment of the present invention.

### BRIEF DESCRIPTION OF THE DRAWINGS

FIG. 1 is a perspective view illustrating by way of example an apparatus for processing a laminated wafer;

FIG. 2 is a side elevational view of a portion of the apparatus illustrated in FIG. 1;

FIG. 3 is a flowchart of a sequence of a method of manufacturing a laminated wafer with a processed outer circumference and a method of manufacturing device chips by way of example;

FIG. 4A is a schematic side elevational view illustrating a process of measuring joint misalignment of a laminated wafer by way of example;

FIG. 4B is a schematic plan view illustrating the process of FIG. 4A;

FIG. 5A is a schematic side elevational view illustrating another process of measuring joint misalignment of a laminated wafer by way of example;

FIG. 5B is a schematic plan view illustrating the process of FIG. 5A;

FIG. 6 is a schematic side elevational view illustrating a process of measuring a position of a first wafer by way of example;

FIG. 7A is a schematic side elevational view illustrating joint misalignment of a laminated wafer;

FIG. 7B is a schematic plan view illustrating the joint misalignment illustrated in FIG. 7A;

FIG. 8 is a cross-sectional view, partly in side elevation, schematically illustrating a process of processing a laminated wafer by way of example;

FIG. 9A is an elevational cross-sectional view schematically illustrating a laminated wafer with a processed outer circumference by way of example;

FIG. 9B is a plan view schematically illustrating the laminated wafer depicted in FIG. 9A;

FIG. 10 is a cross-sectional view, partly in side elevation, schematically illustrating another process of processing a laminated wafer by way of example;

FIG. 11 is a cross-sectional view, partly in side elevation, schematically illustrating a stage of the other process of processing a laminated wafer;

FIG. 12 is a cross-sectional view, partly in side elevation, schematically illustrating another stage of the other process of processing a laminated wafer; and

FIG. 13 is a cross-sectional view, partly in side elevation, schematically illustrating the manner in which a first wafer of the laminated wafer is divided by way of example.

### DETAILED DESCRIPTION OF THE PREFERRED EMBODIMENT

A preferred embodiment of the present invention will be described below with reference to the accompanying drawings.

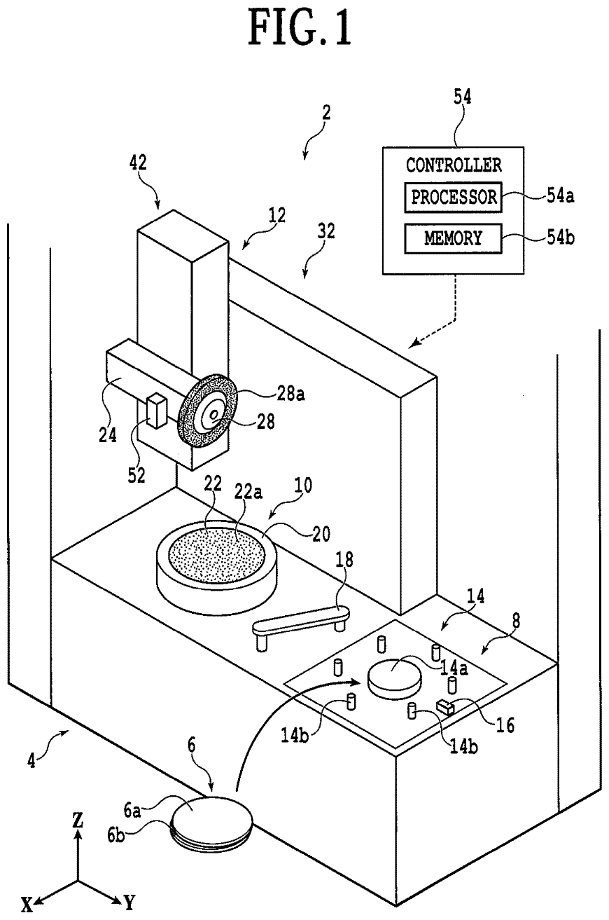

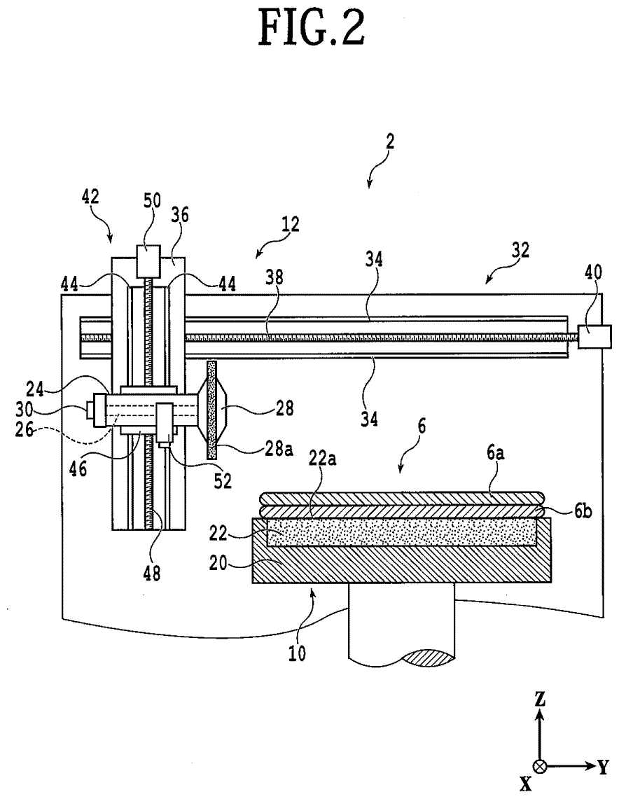

First, a cutting apparatus 2 according to the present embodiment will be described below with reference to FIGS. 1 and 2. FIG. 1 illustrates in perspective by way of example the cutting apparatus 2 as an apparatus for processing a laminated wafer. FIG. 2 illustrates in side elevation a portion of the cutting apparatus 2 illustrated in FIG. 1. In FIG. 1, some components including a cutting mechanism 12 are depicted as simplified for illustrative purposes.

In FIGS. 1 and 2, the cutting apparatus 2 is illustrated in reference to a three-dimensional space including an X-axis, a Y-axis, and a Z-axis that extend perpendicularly to each other. The X-axis and the Y-axis extend horizontally and perpendicularly to each other, and the Z-axis extends vertically and perpendicularly to the X-axis and the Y-axis. The X-axis and the Y-axis jointly define a horizontal plane that may be referred to as an XY plane.

The cutting apparatus 2 includes a base 4 supporting and housing various components thereof, a misalignment measuring mechanism 8 for performing a joint misalignment measuring process, to be described later, on a laminated wafer 6 as a target to be processed, a to-be-processed-wafer holding mechanism 10 as a second holding mechanism for holding the laminated wafer 6 while it is being processed, and a cutting mechanism 12 for cutting the laminated wafer 6.

The laminated wafer 6 to be processed by the cutting apparatus 2 includes a plate-shaped layered wafer assembly made of silicon, for example. The laminated wafer 6 includes a first wafer 6a and a second wafer 6b that are each plate-shaped and stacked together.

The first wafer 6a and the second wafer 6b include disk-shaped wafers that are identical in shape and material to each other and have respective facing surfaces that are joined to each other. These wafers may be joined together by any of various processes including an adhesive bonding process, a process using intermolecular forces, and a thermal compression bonding process, for example. A plurality of ICs or LSI circuits, for example, are constructed in the surface of the first wafer 6a that is not joined to the second wafer 6b. When the cutting apparatus 2 is in operation, it performs an edge trimming process on the outer circumference of the first wafer 6a of the laminated wafer 6. The cutting apparatus 2 may as well be operated to perform the edge trimming process on the outer circumference of the second wafer 6b.

A plurality of devices may be constructed in the surface of the first wafer 6a that is joined to the second wafer 6b.

The second wafer 6b includes a dummy wafer called a non-product (NP) wafer or a quality-control (QC) wafer, for example, and is free of devices.

The first wafer 6a and the second wafer 6b, each of a disk shape, are joined to each other such that their centers are kept in positional alignment with each other as much as possible. However, due to a lack of desired positioning accuracy at the time when the first wafer 6a and the second wafer 6b are joined to each other, the centers of the first wafer 6a and the second wafer 6b may be misaligned with each other, or deviate from each other, by a distance up to a range of 200 to 300 μm, for example, when they are joined to each other. The distance may be referred to as “joint misalignment.” The cutting apparatus 2 according to the present embodiment measures joint misalignment and performs the edge trimming process on the first wafer 6a on the basis of the measured joint misalignment according to a processing sequence to be described later.

The base 4 refers to a frame acting as a foundation for the cutting apparatus 2. The base 4 supports thereon a cover, not depicted, providing an upper surface and side surfaces of the cutting apparatus 2. The cover houses therein the misalignment measuring mechanism 8, the to-be-processed-wafer holding mechanism 10, and the cutting mechanism 12.

The misalignment measuring mechanism 8 includes a to-be-measured-wafer holding mechanism 14 as a first holding mechanism for holding the laminated wafer 6 when it is measured and a detector 16. The to-be-measured-wafer holding mechanism 14 includes a rotary table 14a and a plurality of positioning pegs 14b.

The to-be-measured-wafer holding mechanism 14 is a mechanism equivalent to a mechanism referred to as a positioning table included in a semiconductor processing apparatus, for example. The rotary table 14a refers to a table for placing thereon the laminated wafer 6 to be measured. The rotary table 14a is rotatable about its central axis along the Z-axis with respect to the base 4. The rotary table 14a is rotated by a power mechanism such as an electric motor, not depicted, for example.

The positioning pegs 14b are disposed around the rotary table 14a along the outer circumference of the laminated wafer 6 placed on the rotary table 14a. The positioning pegs 14b protrude upwardly from an upper surface of the base 4. The positioning pegs 14b are disposed in a circular array around the rotary table 14a and are radially movable toward and away from the rotary table 14a while keeping in circular patterns around the rotary table 14a.

When the laminated wafer 6 is to be placed on the rotary table 14a, the positioning pegs 14b are previously positioned away from the rotary table 14a in a circle that is larger in diameter than the laminated wafer 6. Then, the laminated wafer 6 is placed on the rotary table 14a in the center.

A support table, not depicted, is disposed on the upper surface of the base 4 at a position adjacent to the to-be-measured-wafer holding mechanism 14. The support table supports thereon a cassette, not depicted, introduced from outside the cutting apparatus 2. A delivery mechanism, not depicted, such as a robot arm for removing a laminated wafer 6 from the cassette placed on the support table and placing the laminated wafer 6 on the rotary table 14a is disposed on the upper surface of the base 4 at a position near the support table and the to-be-measured-wafer holding mechanism 14. A laminated wafer 6 from the cassette on the support table is placed on the rotary table 14a by the delivery mechanism.

After the laminated wafer 6 has been placed on the rotary table 14a, the positioning pegs 14b are moved radially inwardly into contact with the outer circumference of the laminated wafer 6.

Since the positioning pegs 14b are moved radially inwardly while keeping a circular layout, they push the laminated wafer 6 that may have been misaligned with the rotary table 14a until the centers of the rotary table 14a and the laminated wafer 6 are brought into alignment with each other, thereby positioning the laminated wafer 6 in alignment with the rotary table 14a.

Thus, the to-be-measured-wafer holding mechanism 14 functions as a positioning table for the laminated wafer 6 in the cutting apparatus 2. In addition, the to-be-measured-wafer holding mechanism 14 also functions to hold the laminated wafer 6 when it is measured for joint misalignment. The joint misalignment is measured by the detector 16 while the laminated wafer 6 is being placed on the rotary table 14a.

The detector 16 includes an image capturing device such as a camera having a lens or a device such as a laser sensor, for example. The detector 16 can detect the distance between itself and a target to be measured. The target to be measured by the detector 16 may be the outer circumferences of the first wafer 6a and the second wafer 6b of the laminated wafer 6 that is placed on the rotary table 14a. The detector 16 may alternatively be any of various devices capable of measuring the distance up to the target, instead of a camera or a laser sensor. Details of a process of measuring joint misalignment with the misalignment measuring mechanism 8 will be described later.

The detector 16 is installed at a position spaced radially outwardly from the laminated wafer 6 held on the rotary table 14a and faces a side surface of the laminated wafer 6 that represents the outer circumference thereof. The detector 16 measures the position of the outer circumference of the laminated wafer 6 from the position where it is installed.

The outer circumference of a wafer, i.e., the laminated wafer 6, the first wafer 6a, or the second wafer 6b, described herein refers to a portion of the wafer that defines the contour of the wafer in a field of vision where the wafer is viewed from a direction perpendicular to the edge of the wafer, i.e., a side surface of the wafer regarded as a short columnar cylindrical object.

When the laminated wafer 6 placed in the to-be-measured-wafer holding mechanism 14 is positioned with respect to the base 4 by the positioning pegs 14b, the positions of the outer circumferences of the first and second wafers 6a and 6b are measured by the misalignment measuring mechanism 8. Thereafter, the laminated wafer 6 is transferred to the to-be-processed-wafer holding mechanism 10.

The laminated wafer 6 is transferred from the to-be-measured-wafer holding mechanism 14 to the to-be-processed-wafer holding mechanism 10 by a delivery mechanism 18 disposed on the upper surface of the base 4 at a position near the to-be-measured-wafer holding mechanism 14 and the to-be-processed-wafer holding mechanism 10. The delivery mechanism 18 includes a robot arm, for example.

The to-be-processed-wafer holding mechanism 10 includes a chuck table, for example, for holding the laminated wafer 6 under suction. The to-be-processed-wafer holding mechanism 10 has a lower portion coupled to a rotating mechanism, not depicted, for rotating the to-be-processed-wafer holding mechanism 10 about its central axis extending along the Z-axis perpendicularly to a holding surface 22a thereof to be described later.

The lower portion of the to-be-processed-wafer holding mechanism 10 is also coupled to an X-axis moving mechanism, not depicted, for moving the to-be-processed-wafer holding mechanism 10 and the rotating mechanism along the X-axis. The X-axis moving mechanism includes a mechanism for moving a spindle 26 of the cutting mechanism 12 on which a cutting blade 28 is mounted as described later and the to-be-processed-wafer holding mechanism 10 relatively to each other along the X-axis. According to the present embodiment, the X-axis moving mechanism moves the to-be-processed-wafer holding mechanism 10 in directions along the X-axis with respect to the spindle 26 of the cutting mechanism 12.

The X-axis moving mechanism may alternatively move the spindle 26 rather than the to-be-processed-wafer holding mechanism 10 or move both the to-be-processed-wafer holding mechanism 10 and the spindle 26.

The to-be-processed-wafer holding mechanism 10, as the chuck table, includes a disk-shaped table base 20 made of metal, for example, and a circular suction plate 22 mounted on the table base 20.

The suction plate 22 includes a disk-shaped plate made of porous ceramic, for example. The table base 20 has a circular recess defined in an upper portion thereof and having dimensions commensurate with the dimensions of the suction plate 22. The suction plate 22 is securely fitted in the recess. The table base 20 has a fluid channel, not depicted, defined therein that has an end fluidly connected to a lower surface of the suction plate 22.

The other end of the fluid channel in the table base 20 is fluidly connected to a suction source, not depicted, such as an ejector, for example. When the suction source is activated, it generates and transmits a negative pressure through the fluid channel to an object such as the laminated wafer 6 placed on an upper surface of the suction plate 22. The upper surface of the suction plate 22 acts as the holding surface 22a referred to above. The suction plate 22 may alternatively include a metal plate having a plurality of holes extending thicknesswise vertically through itself, for example.

The cutting mechanism 12 is disposed above the to-be-processed-wafer holding mechanism 10. The cutting mechanism 12 includes a spindle housing 24 and the spindle 26 rotatably housed in the spindle housing 24.

The spindle housing 24 includes a hollow elongate case having a rectangular shape as a whole and has a longitudinal axis extending along the Y-axis. As illustrated in FIG. 2, the spindle 26 that is shaped as a cylindrical rod is mostly housed in the spindle housing 24.

The spindle 26 is housed in the spindle housing 24 such that the longitudinal axis of the spindle 26 extends along the Y-axis. The spindle 26 is rotatable about its longitudinal axis with respect to the spindle housing 24.

The spindle 26 has an axial end protruding out of the spindle housing 24. A circular cutting blade 28 is mounted on the protruding axial end of the spindle 26. The cutting blade 28 includes a hub-type blade, for example, and includes a disk-shaped base made of metal such as aluminum, for example, and an annular cutting edge 28a mounted on an outer circumferential edge of the base.

The cutting edge 28a has a thickness larger than the thickness of the cutting edge of a cutting blade that is used to divide a semiconductor wafer into a plurality of device chips, for example. The thickness of the cutting edge 28a ranges from 1 to 3 mm, for example.

To the other end of the spindle 26, there is coupled a rotary actuator 30 such as a servomotor, for example, that, when energized, rotates the spindle 26 together with the cutting blade 28.

The spindle housing 24 is movably supported on the base 4 by a Y-axis moving mechanism 32 and a Z-axis moving mechanism 42 for movement respectively along the Y-axis and the Z-axis with respect to the base 4.

The Y-axis moving mechanism 32 and the Z-axis moving mechanism 42 refer to mechanisms for moving the spindle 26 with the cutting blade 28 mounted thereon and the to-be-processed-wafer holding mechanism 10 with the laminated wafer 6 held thereby relatively to each other respectively along the Y-axis and the Z-axis. According to the present embodiment, the Y-axis moving mechanism 32 and the Z-axis moving mechanism 42 move the spindle 26 along the Y-axis and the Z-axis, respectively, with respect to the to-be-processed-wafer holding mechanism 10. The Y-axis moving mechanism 32 and the Z-axis moving mechanism 42 may alternatively move the to-be-processed-wafer holding mechanism 10 rather than the spindle 26 or move both the to-be-processed-wafer holding mechanism 10 and the spindle 26.

As illustrated in FIG. 2, the Y-axis moving mechanism 32 includes a pair of guide rails 34 disposed on the base 4 and extending along the Y-axis and a Y-axis movable table 36 slidably mounted on the guide rails 34. A ball screw 38 extending along the Y-axis is disposed between the guide rails 34.

The ball screw 38 is rotatably threaded through a nut, not depicted, fixedly mounted on a reverse side of the Y-axis movable table 36. The ball screw 38 has an end coupled to a rotary actuator 40 such as a stepping motor, for example. When the rotary actuator 40 is energized, it rotates the ball screw 38 about its central longitudinal axis, causing the nut to move the Y-axis movable table 36 along the Y-axis.

The Z-axis moving mechanism 42 is coupled to the Y-axis movable table 36. The Z-axis moving mechanism 42 includes a pair of guide rails 44 disposed on the Y-axis movable table 36 and extending along the Z-axis and a Z-axis movable table 46 slidably mounted on the guide rails 44. A ball screw 48 extending along the Z-axis is disposed between the guide rails 44.

The spindle housing 24 is fixed to a face side of the Z-axis movable table 46. The ball screw 48 is rotatably threaded through a nut, not depicted, fixedly mounted on a reverse side of the Z-axis movable table 46. The ball screw 48 has an upper end coupled to a rotary actuator 50 such as a stepping motor, for example. When the rotary actuator 50 is energized, it rotates the ball screw 48 about its central longitudinal axis, causing the nut to move the Z-axis movable table 46 together with the spindle housing 24 along the Z-axis.

An image capturing device 52 that includes a camera is mounted on the spindle housing 24 fixed to the Z-axis movable table 46. The image capturing device 52 is positioned above the chuck table as the to-be-processed-wafer holding mechanism 10. When the image capturing device 52 is in operation, it captures an image of the laminated wafer 6 held on the to-be-processed-wafer holding mechanism 10 and inputs image data of the captured image as a data signal to a controller 54 (see FIG. 1).

The controller 54 controls operation of various components of the cutting apparatus 2 that includes the misalignment measuring mechanism 8, the to-be-processed-wafer holding mechanism 10, the cutting mechanism 12, the delivery mechanism 18, and the image capturing device 52. According to the present embodiment, the controller 54 of the cutting apparatus 2 has a function to acquire values regarding the positions of the first and second wafers 6a and 6b of the laminated wafer 6 and cut the laminated wafer 6 while adjusting the relative positional relation between the to-be-processed-wafer holding mechanism 10 and the cutting blade 28 on the basis of the acquired values regarding the positions.

The controller 54 includes a computer having a processor 54a, typically a central processing unit (CPU), and a memory 54b. The memory 54b includes a main storage unit such as a dynamic random access memory (DRAM), and an auxiliary storage unit such as a flash memory.

The auxiliary storage unit stores software. The processor 54a is operated according to the software stored in the auxiliary storage unit to perform the function of the controller 54.

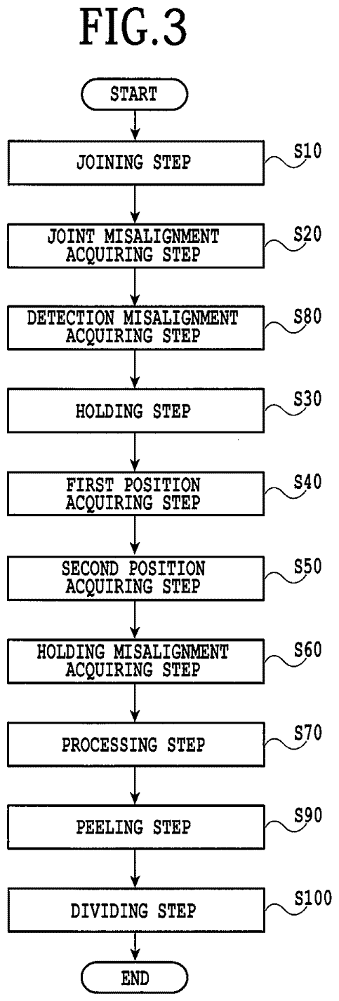

A process of measuring and processing the laminated wafer 6 with the cutting apparatus 2 will be described below with reference to FIG. 3. FIG. 3 is a flowchart of the sequence of a method of manufacturing a laminated wafer with a processed outer circumference of the laminated wafer 6 by way of example.

The sequence of the method illustrated in FIG. 3 includes a joining step S10, a joint misalignment acquiring step S20, a detection misalignment acquiring step S80, a holding step S30, a first position acquiring step S40, a second position acquiring step S50, a holding misalignment acquiring step S60, a processing step S70, a peeling step S90, and a dividing step S100.

In the joining step S10, the first wafer 6a and the second wafer 6b, each shaped as a plate, have their facing surfaces joined to each other, making up the laminated wafer 6 (see FIG. 1).

The laminated wafer 6 thus produced is loaded into the cutting apparatus 2 in which the laminated wafer 6 is placed on the rotary table 14a of the to-be-measured-wafer holding mechanism 14. Then, the misalignment measuring mechanism 8 performs the joint misalignment acquiring step S20 on the laminated wafer 6. In the joint misalignment acquiring step S20, while the laminated wafer 6 is being held by the to-be-measured-wafer holding mechanism 14, the misalignment measuring mechanism 8 measures respective positions of the outer circumference of the first wafer 6a and the outer circumference of the second wafer 6b, thereby acquiring a value of joint misalignment between the first wafer 6a and the second wafer 6b.

The value of joint misalignment refers to the amount and/or angle of joint misalignment, and may be acquired as one of the values described below. In addition, the value of joint misalignment may also represent any of various parameters other than the values described below.

### (Amount of Joint Misalignment)

the distance between the position of the center of the disk-shaped first wafer 6a and the position of the center of the disk-shaped second wafer 6b that is equal in diameter to the first wafer 6a,
the distance between the position of a particular portion of the first wafer 6a and the position of a particular portion of the second wafer 6b that corresponds to the particular portion of the first wafer 6a, and
the maximum width of a portion of the outer circumference of the second wafer 6b, which is identical in shape to the first wafer 6a, protruding radially outwardly from the outer circumference of the first wafer 6a as viewed in plan, i.e., in a field of vision where the laminated wafer 6 is viewed from a direction perpendicular to the planes of the first and second wafers 6a and 6b.

### (Orientation of Joint Misalignment)

the angle of a straight line interconnecting the centers of the first and second wafers 6a and 6b from a hypothetical reference line while the laminated wafer 6 is being held on the rotary table 14a of the to-be-measured-wafer holding mechanism 14,
the orientation of a portion of the outer circumference of the second wafer 6b protruding by a greatest amount radially outwardly from the outer circumference of the first wafer 6a with respect to the rotary table 14a while the laminated wafer 6 is being held on the rotary table 14a of the to-be-measured-wafer holding mechanism 14, and
the angle of a straight line interconnecting the center of the first wafer 6a or the second wafer 6b and a notch defined in the outer circumference of the first wafer 6a or the second wafer 6b from a hypothetical reference line.

According to the present embodiment, the misalignment measuring mechanism 8 measures a value of joint misalignment as follows.

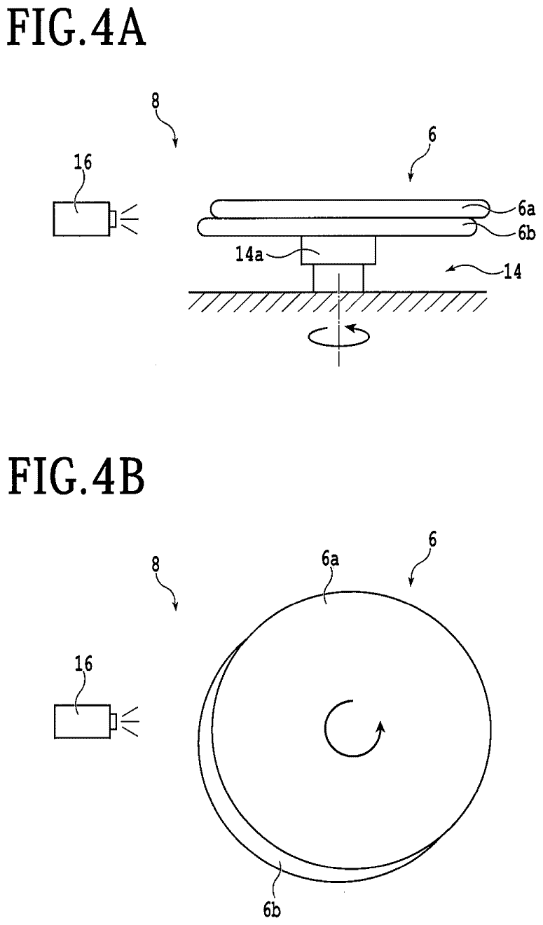

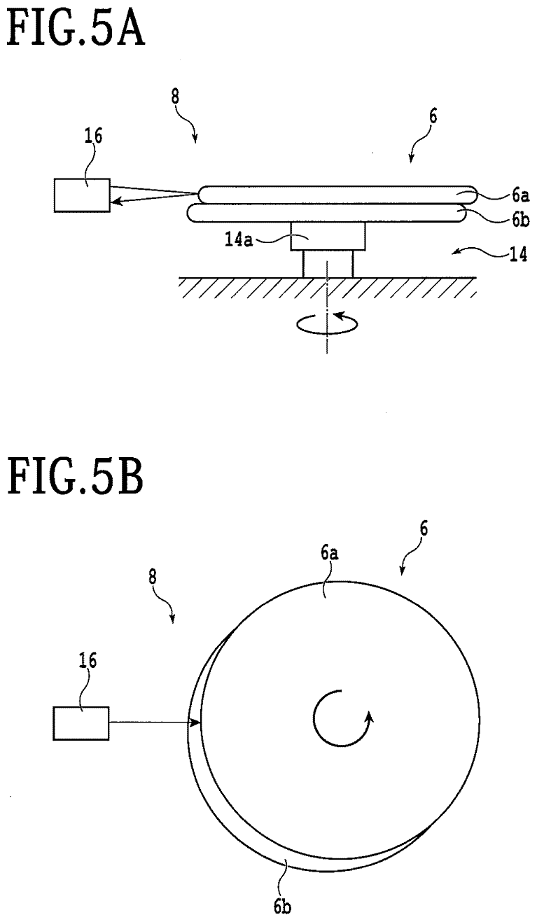

FIGS. 4A, 4B, 5A, and 5B schematically illustrate different processes of measuring joint misalignment of the laminated wafer 6 by way of example. FIGS. 4A and 5A illustrate the processes in side elevation, whereas FIGS. 4B and 5B illustrate the processes in plan.

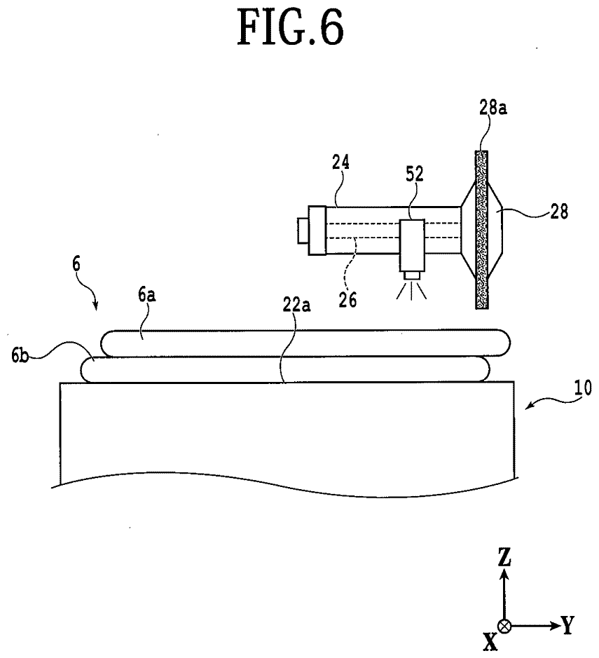

In FIGS. 4A, 4B, 5A, and 5B, the thicknesses of the wafers and the joint misalignment are depicted as exaggerated for illustrative purposes. The same hold true for FIGS. 6 through 13.

FIGS. 4A and 4B schematically illustrate the manner in which joint misalignment is measured by the detector 16 that includes a microscope camera, for example. In a case where the detector 16 is a microscope camera, the relative positional relation between a side surface of the laminated wafer 6 and the detector 16 can be grasped using the focal length of the microscope camera.

Specifically, for example, the microscope camera as the detector 16 captures an image of a portion of the side surface of the laminated wafer 6, and the distance between the captured portion of the side surface of the laminated wafer 6 and the detector 16 is grasped from the focal length of the microscope camera in a case where the image is focused. The distance is acquired in this fashion while the laminated wafer 6 is being rotated by the rotary table 14a. By recording the distances up to successive portions of the side surface of the laminated wafer 6 measured by the detector 16 in association with successive values of the angle of the rotary table 14a, the positions of the portions of the side surface of the laminated wafer 6 around the center of the rotary table 14a can be grasped.

Since the laminated wafer 6 is made up of the first wafer 6a and the second wafer 6b that are stacked together, the above measuring process is performed with respect to the height at which the first wafer 6a is positioned and the height at which the second wafer 6b is positioned. Therefore, the positions of the respective portions of the side surface representing the outer circumferences of the first wafer 6a and the second wafer 6b can be grasped.

For example, in a case where the first wafer 6a is of a disk shape, the position of its center can be specified as coordinates, for example, if the positions of a plurality of portions, i.e., three or more positions of the outer circumference of the first wafer 6a can be acquired. The position of the second wafer 6b that is of a disk shape can also be specified in the same manner. An amount and orientation of joint misalignment between the first wafer 6a and the second wafer 6b can thus be acquired. Concurrently, the positions of the outer circumferences and centers of the first wafer 6a and the second wafer 6b with respect to the rotary table 14a can also be acquired.

FIGS. 5A and 5B schematically illustrate the manner in which joint misalignment is measured by the detector 16 that includes a laser sensor, for example. In a case where the detector 16 is a laser sensor, the relative positional relation between a side surface of the laminated wafer 6 and the detector 16 can be grasped by applying the principle of a triangulation ranging process, a phase difference ranging process, or a pulse propagation ranging process, for example.

Using the laser sensor as the detector 16, while the rotary table 14a with the laminated wafer 6 placed thereon is rotating, the distances up to successive portions of the side surfaces of the first and second wafers 6a and 6b measured by the detector 16 in association with successive values of the angle of the rotary table 14a are recorded. Consequently, an amount and orientation of joint misalignment between the first wafer 6a and the second wafer 6b, the positions of the outer circumferences and centers of the first wafer 6a and the second wafer 6b with respect to the rotary table 14a, and the diameters of the first and second wafers 6a and 6b can be acquired.

Then, the detection misalignment acquiring step S80 of the sequence of the method illustrated in FIG. 3 is carried out.

In the joint misalignment acquiring step S20 described above, the detector 16 that may be a microscope camera or a laser sensor measures the positions of the respective portions of the side surfaces of the first and second wafers 6a and 6b, and a value of joint misalignment between the first and second wafers 6a and 6b and the positions and dimensions of the first and second wafers 6a and 6b are acquired on the basis of the measured positions.

The dimensions and positional relations of various parts of the detector 16 and the relative positional relation between the detector 16 and the laminated wafer 6 may be slightly varied due to temperature changes of the detector 16 itself and temperature changes of a structure that supports the laminated wafer 6 and the detector 16. Such dimensional and positional variations may possibly cause changes in the distances between the detector 16 and the first and second wafers 6a and 6b.

Such changes in the distances do not adversely affect the amount of joint misalignment because joint misalignment is grasped as the relative positional relation between the first and second wafers 6a and 6b, not the distance from the detector 16. However, the changes in the distances may cause a measurement error regarding the diameters of the first and second wafers 6a and 6b, for example.

According to the sequence of the method illustrated in FIG. 3, the outer circumference of the first wafer 6a, for example, is cut in the processing step S70. In the processing step S70, the first wafer 6a is cut on the basis of the position of the second wafer 6b as a reference position. In order to correctly adjust the width across which to cut the outer circumference of the first wafer 6a, it is desirable that the diameter of the second wafer 6b be properly grasped. However, a measurement error may possibly occur regarding the diameter of the second wafer 6b for the reasons described above.

In the detection misalignment acquiring step S80, therefore, the distance between the side surface of the rotary table 14a and the detector 16 is measured, so that the position of the detector 16 with respect to the to-be-measured-wafer holding mechanism 14 is acquired. In this manner, misalignment of the detector 16 from a fixed position due to temperature changes and the like is detected.

For example, when the distance between the detector 16 and various portions of the side surface of the second wafer 6b has been measured and the diameter of the second wafer 6b is to be calculated on the basis of the measured distance, the diameter of the second wafer 6b can be calculated accurately by taking the detected misalignment into account. The calculated diameter of the second wafer 6b will be used in a subsequent step to make it possible to process the laminated wafer 6 with higher accuracy.

In FIG. 3, the detection misalignment acquiring step S80 is carried out after the joint misalignment acquiring step S20 for illustrative purposes. However, the detection misalignment acquiring step S80 may be carried out at the same time as the joint misalignment acquiring step S20 or may be carried out before the joint misalignment acquiring step S20. Further alternatively, the detection misalignment acquiring step S80 may be carried out at any time after the holding step S30 and before the processing step S70.

After the value of joint misalignment between the first wafer 6a and the second wafer 6b and the value of the position of the detector 16 with respect to the to-be-measured-wafer holding mechanism 14 have been acquired, the holding step S30 is carried out. The laminated wafer 6 held by the to-be-measured-wafer holding mechanism 14 is delivered to the to-be-processed-wafer holding mechanism 10 by the delivery mechanism 18.

On the chuck table as the to-be-processed-wafer holding mechanism 10, the laminated wafer 6 is held such that the second wafer 6b of the laminated wafer 6 is attracted under suction to the holding surface 22a and the first wafer 6a of the laminated wafer 6 is exposed upwardly.

With the laminated wafer 6 held by the to-be-processed-wafer holding mechanism 10, the first position acquiring step S40 is carried out. In the first position acquiring step S40, the position of the first wafer 6a of the laminated wafer 6 held by the to-be-processed-wafer holding mechanism 10 is acquired on the basis of the positions of a plurality of points on the outer circumference of the first wafer 6a.

In the first position acquiring step S40, the position of the first wafer 6a is specified by the image capturing device 52 that is disposed above the to-be-processed-wafer holding mechanism 10, as illustrated in FIG. 6. FIG. 6 schematically illustrates in side elevation a process of measuring the position of the first wafer 6a by way of example.

The image capturing device 52 acquires at least an image of a portion of the outer circumference of the laminated wafer 6 held by the to-be-processed-wafer holding mechanism 10 from above, i.e., from a position spaced from the laminated wafer 6 in a direction perpendicular to the plane of the first wafer 6a, and inputs the acquired image to the controller 54. In a case where the first wafer 6a is of a disk shape that is circular as viewed in plan, if the positions of at least three points on the outer circumference of the first wafer 6a are measured, then the position of the center of the first wafer 6a can be specified.

Even in a case where the first wafer 6a is not circular in shape as viewed in plan, providing that the shape and dimensions of the first wafer 6a have been specified beforehand, the position of the first wafer 6a with respect to the to-be-processed-wafer holding mechanism 10 can be specified by measuring the positions of a plurality of points on the outer circumference of the first wafer 6a that defines the contour of the first wafer 6a.

Since the laminated wafer 6 has been held by the to-be-processed-wafer holding mechanism 10 in such a posture that the first wafer 6a is exposed upwardly, it is easy for the image capturing device 52 to acquire an image of the first wafer 6a from above for measuring the positions of suitable points on the outer circumference of the first wafer 6a.

Then, the second position acquiring step S50 is carried out. In the second position acquiring step S50, the position of the second wafer 6b with respect to the to-be-processed-wafer holding mechanism 10 is acquired on the basis of the value of joint misalignment acquired in the joint misalignment acquiring step S20 and the position of the first wafer 6a acquired in the first position acquiring step S40.

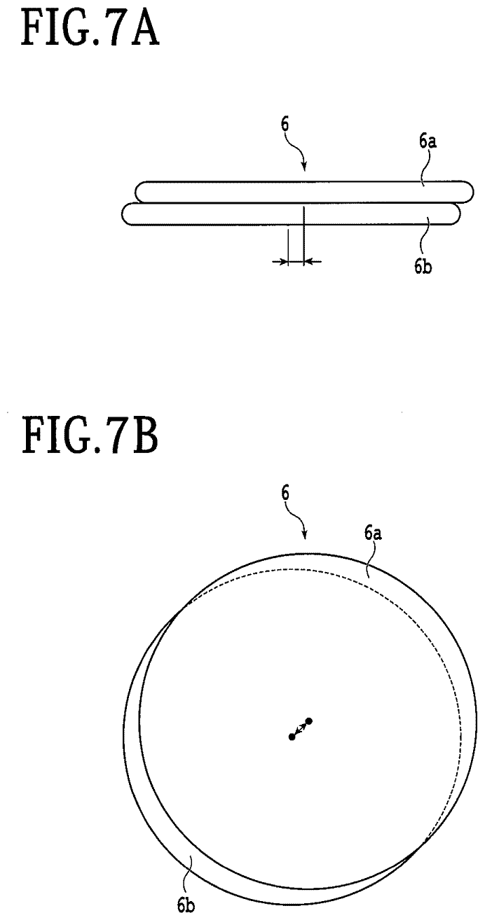

FIGS. 7A and 7B illustrate joint misalignment of the laminated wafer 6 respectively in side elevation and plan. As illustrated in FIG. 7B, joint misalignment between the first wafer 6a and the second wafer 6b is equivalent to the difference between the position of the center of the first wafer 6a and the position of the center of the second wafer 6b, for example. Consequently, once the value of joint misalignment is acquired as well as the position of the center of the first wafer 6a, the position of the center of the second wafer 6b can be specified on the basis of those items of information.

The laminated wafer 6 is made up of the first and second wafers 6a and 6b that are disk-shaped and equal in diameter to each other, as described above. In a case where the misalignment between the positions of the centers of the first wafer 6a and the second wafer 6b, i.e., the amount and orientation of joint misalignment therebetween, has been acquired in the joint misalignment acquiring step S20 and the positional coordinates of the center of the first wafer 6a have been acquired in the first position acquiring step S40, it is possible to calculate the position of the second wafer 6b as the positional coordinates of the center of the second wafer 6b by adding the amount of joint misalignment to or subtracting the amount of joint misalignment from the positional coordinates of the center of the first wafer 6a.

The amount and orientation of joint misalignment of the laminated wafer 6 have been measured by the misalignment measuring mechanism 8 while the laminated wafer 6 is being held by the to-be-measured-wafer holding mechanism 14. Thereafter, the laminated wafer 6 has been delivered from the to-be-measured-wafer holding mechanism 14 to the to-be-processed-wafer holding mechanism 10 by the delivery mechanism 18. Unless the laminated wafer 6 is positionally shifted or turned unexpectedly during its delivery from the to-be-measured-wafer holding mechanism 14 to the to-be-processed-wafer holding mechanism 10, the data regarding the value of joint misalignment acquired on the to-be-measured-wafer holding mechanism 14 can be used safely in the second position acquiring step S50.

Instead of specifying the position of the second wafer 6b according to the process described above, it is possible in some cases to specify the position of the center of the second wafer 6b on the basis of an image captured of a portion of the outer circumference of the second wafer 6b with the image capturing device 52, for example (see, for example, Japanese Patent Laid-open No. 2016-96295).

However, the second wafer 6b is positioned behind the first wafer 6a as viewed from the image capturing device 52. Therefore, if the amount of joint misalignment is too small, for example, then the outer circumference of the second wafer 6b may be obstructed by the first wafer 6a and fail to be exposed sufficiently in the field of vision of the image capturing device 52, with the result that the position of the center of the second wafer 6b may not be specified or may be specified with a reduced level of accuracy.

The position of the second wafer 6b can be acquired reliably with high accuracy according to the above process of specifying the position of the first wafer 6a on the basis of the image acquired by the image capturing device 52 and specifying the position of the second wafer 6b additionally on the basis of the joint misalignment measured using the detector 16.

After the position of the second wafer 6b with respect to the to-be-processed-wafer holding mechanism 10 has been specified, the holding misalignment acquiring step S60 is carried out to measure positional misalignment of the second wafer 6b with respect to the to-be-processed-wafer holding mechanism 10.

When the laminated wafer 6 is introduced into the cutting apparatus 2, the laminated wafer 6 is first placed on the rotary table 14a of the to-be-measured-wafer holding mechanism 14 acting as the positioning table. After the laminated wafer 6 has been positioned on the rotary table 14a by the positioning pegs 14b, the laminated wafer 6 is delivered to the to-be-processed-wafer holding mechanism 10 by the delivery mechanism 18. Unless the laminated wafer 6 is positionally or angularly shifted unexpectedly while being delivered by the delivery mechanism 18, the laminated wafer 6 is positioned to a certain degree with respect to the to-be-processed-wafer holding mechanism 10 when the laminated wafer 6 is held by the to-be-processed-wafer holding mechanism 10.

Nevertheless, the positioning pegs 14b that are used for positioning the laminated wafer 6 cannot be expected to position the laminated wafer 6 with high accuracy. In addition, as described above, it is predicted that joint misalignment may occur between the first wafer 6a and the second wafer 6b of the laminated wafer 6.

Consequently, each time the laminated wafer 6 is held by the chuck table as the to-be-processed-wafer holding mechanism 10, the positions of the laminated wafer 6 and the second wafer 6b are not strictly adjusted with respect to the to-be-processed-wafer holding mechanism 10.

In the processing step S70 to be performed later, the cutting blade 28 is brought into cutting contact with the laminated wafer 6 that is rotating with the to-be-processed-wafer holding mechanism 10 to cut the laminated wafer 6. Therefore, the position of the second wafer 6b with respect to the to-be-processed-wafer holding mechanism 10 can affect the position where the cutting blade 28 cuts the laminated wafer 6 in the processing step S70.

If the axis about which the to-be-processed-wafer holding mechanism 10 rotates, hereinafter referred to as “rotational axis,” and the central axis of the disk-shaped second wafer 6b are aligned with each other, then it is possible to process the laminated wafer 6 symmetrically with respect to the central axis of the second wafer 6b by placing the cutting blade 28 at a constant position with respect to the to-be-processed-wafer holding mechanism 10 while the to-be-processed-wafer holding mechanism 10 is in rotation. Conversely, if the rotational axis of the to-be-processed-wafer holding mechanism 10 and the central axis of the disk-shaped second wafer 6b are not aligned with each other, then in order to process the laminated wafer 6 symmetrically with respect to the central axis of the second wafer 6b, it is necessary to adjust the relative positions of the to-be-processed-wafer holding mechanism 10 and the cutting blade 28 upon rotation of the to-be-processed-wafer holding mechanism 10.

In the holding misalignment acquiring step S60, for the purpose of processing the laminated wafer 6 taking into account the position of the second wafer 6b with respect to the to-be-processed-wafer holding mechanism 10 in the processing step S70, a value of misalignment between the position of the rotational axis of the to-be-processed-wafer holding mechanism 10 and the position of the center of the second wafer 6b held by the to-be-processed-wafer holding mechanism 10 is acquired.

The “value of misalignment” to be acquired here refers to one of the values described below. However, any of various values other than the values described below may be acquired as the “value of misalignment.”
the difference between positional coordinates of the center of the second wafer 6b acquired in the second position acquiring step S50 and positional coordinates of the rotational axis of the to-be-processed-wafer holding mechanism 10,
the distance and orientation of the position of the rotational axis of the to-be-processed-wafer holding mechanism 10 with respect to the position of the center of the second wafer 6b, and
the positional coordinates of the center of the second wafer 6b acquired in the second position acquiring step S50.

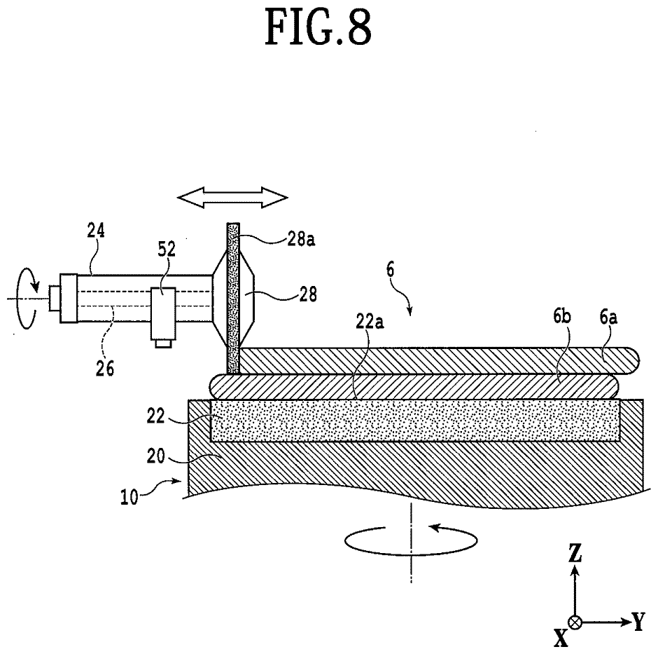

Then, the processing step S70 is carried out. FIG. 8 schematically illustrates in cross section, partly in side elevation, the manner in which the laminated wafer 6 is processed, i.e., cut, by way of example.

In the processing step S70, the cutting blade 28 is disposed in a position where the cutting blade 28 is spaced from the laminated wafer 6 along the X-axis or the Z-axis or both the X-axis and the Z-axis, and the outer circumference of the first wafer 6a and the cutting blade 28 are kept in positional alignment with each other along the Y-axis.

Then, the cutting blade 28 is rotated together with the spindle 26 about its central axis along the Y-axis, and the laminated wafer 6 is rotated together with the to-be-processed-wafer holding mechanism 10 about its central axis along the Z-axis.

While the cutting blade 28 and the laminated wafer 6 are being rotated, they are relatively moved closer to each other along the X-axis or the Z-axis or both the X-axis and the Z-axis until the cutting blade 28 and the laminated wafer 6 contact each other, whereupon the cutting blade 28 starts cutting the laminated wafer 6.

The cutting blade 28 cuts into the outer circumference of the first wafer 6a positioned over the second wafer 6b of the laminated wafer 6, cutting off wafer fragments from the circumference of the first wafer 6a. At this time, the controller 54 controls the cutting blade 28 to cut the circumference of the first wafer 6a, using as a reference the position, i.e., the coordinates of the center, of the second wafer 6b acquired in the second position acquiring step S50, rather than the position of the first wafer 6a.

For example, for cutting the outer circumference of a disk-shaped blank first wafer 6a that has a radius “r” to obtain a disk-shaped processed first wafer 6a having a radius “r-d,” the controller 54 controls the cutting blade 28 to cut the blank first wafer 6a to reach a target represented by the distance “r-d” from the coordinates of the center of the second wafer 6b, instead of reaching a target represented by the distance “r-d” from the coordinates of the center of the first wafer 6a or instead of removing wafer fragments across a width “d” from the circumference of the first wafer 6a.

As described above, positional misalignment, i.e., joint misalignment, may occur between the first wafer 6a and the second wafer 6b due to a lack of desired positioning accuracy at the time when the first wafer 6a and the second wafer 6b are joined to each other (see FIGS. 7A and 7B). If the outer circumference of the first wafer 6a is cut using its own position as a reference in the presence of such joint misalignment, then the joint misalignment remains unremoved between the position of the center of the first wafer 6a after it has been cut and the position of the center of the second wafer 6b.

Depending on the amount of joint misalignment, a portion of the outer circumference of the first wafer 6a that is not joined to the second wafer 6b may remain uncut after the first wafer 6a has been cut. As the outer circumferences of the first and second wafers 6a and 6b have been beveled, the portion of the outer circumference of the first wafer 6a is not joined to the second wafer 6b. Consequently, if the outer circumference of the first wafer 6a is cut on the basis of the position of the first wafer 6a as a reference, then the unjoined portion of the outer circumference of the first wafer 6a tends to remain uncut, providing that the second wafer 6b is positionally misaligned with the first wafer 6a.

If the first wafer 6a is ground with the unjoined portion remaining on the outer circumference thereof, then the first wafer 6a is ground while the unjoined portion is not being supported by the second wafer 6b, making it highly possible for the unjoined portion and other nearby portions of the first wafer 6a to chip or crack.

According to the present embodiment, the cutting apparatus 2 cuts the outer circumference of the first wafer 6a on the basis of the position of the center of the second wafer 6b as a reference in the processing step S70.

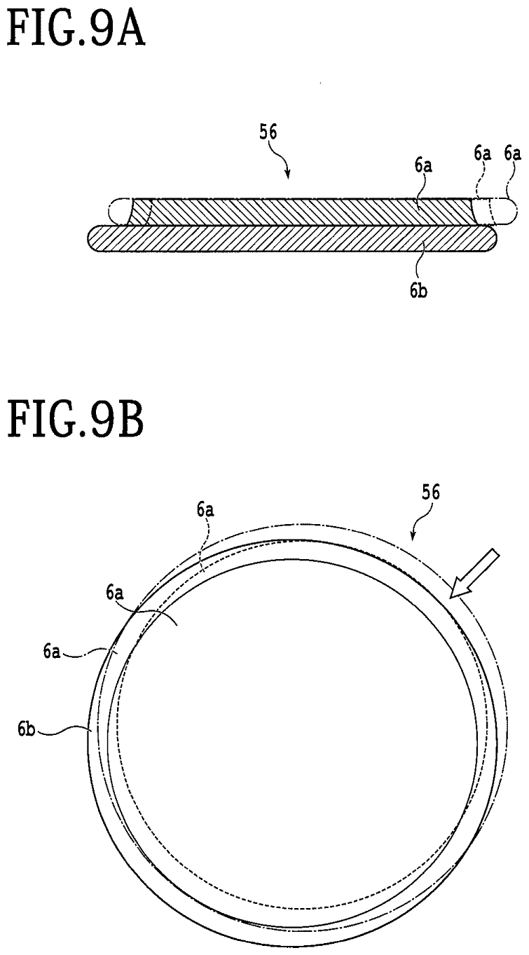

FIG. 9A schematically illustrates in elevational cross section a laminated wafer 56 with a processed outer circumference, which is obtained by processing the laminated wafer 6, i.e., cutting the first wafer 6a, by way of example. FIG. 9B schematically illustrates in plan the laminated wafer 56 depicted in FIG. 9A.

In FIGS. 9A and 9B, the solid lines indicate the contours of the first and second wafers 6a and 6b after the laminated wafer 6 has been cut. The dot-and-dash lines indicate the contour of the first wafer 6a before the first wafer 6a is cut. The broken lines indicate the contour of the first wafer 6a if the outer circumference of the first wafer 6a is cut on the basis of the position of the center of the first wafer 6a as a reference.

As indicated by the broken lines in FIG. 9B, if the outer circumference of the first wafer 6a is cut on the basis of the position of the center of the first wafer 6a as a reference, then since the joint misalignment remains between the first wafer 6a and the second wafer 6b, an unjoined region may be likely to remain near the portion indicated by the arrow in FIG. 9B.

On the other hand, when the outer circumference of the first wafer 6a is cut on the basis of the position of the center of the second wafer 6b as a reference, then since the first wafer 6a is cut symmetrically with respect to the central axis of the second wafer 6b, an unjoined region may be less likely to remain on the outer circumference of the first wafer 6a after it has been cut.

The controller 54 controls the cutting blade 28 to cut the outer circumference of the first wafer 6a while adjusting the position of the cutting blade 28 with respect to the to-be-processed-wafer holding mechanism 10 to match the angle of the to-be-processed-wafer holding mechanism 10 on the basis of the value of misalignment acquired in the holding misalignment measuring step S60.

If there is misalignment between the rotational axis of the to-be-processed-wafer holding mechanism 10 and the position of the center of the second wafer 6b, then the distance between the rotational axis of the to-be-processed-wafer holding mechanism 10 and the outer circumference of the second wafer 6b varies depending on the position where the distance is measured. For this reason, at the time when the laminated wafer 6 is cut while the to-be-processed-wafer holding mechanism 10 is in rotation, the controller 54 controls the Y-axis moving mechanism 32 to move the cutting blade 28 depending on the angle through which the to-be-processed-wafer holding mechanism 10 has turned, i.e., to move the cutting blade 28 away from the rotational axis of the to-be-processed-wafer holding mechanism 10 for cutting a portion of the outer circumference of the second wafer 6b that is far from the rotational axis and to move the cutting blade 28 closely to the rotational axis of the to-be-processed-wafer holding mechanism 10 for cutting a portion of the outer circumference of the second wafer 6b that is close to the rotational axis.

In this manner, even in the presence of misalignment between the rotational axis of the to-be-processed-wafer holding mechanism 10 and the position of the center of the second wafer 6b, the laminated wafer 6 can be processed symmetrically with respect to the center of the second wafer 6b, on the basis of the position of the center of the second wafer 6b as a reference.

According to the sequence of the method illustrated in FIG. 3, the detection misalignment acquiring step S80 is carried out in addition to the joint misalignment acquiring step S20. In the processing step S70 described above, when the outer circumference of the first wafer 6a is cut, in order to obtain a laminated wafer with a processed outer circumference having a predetermined radius “r-d,” an annular region extending radially inwardly from the outer circumference of a circle having a radius “r” across a width “d” is cut off the first wafer 6a.

At this time, the first wafer 6a is cut on the basis of the position of the center of the second wafer 6b as a reference. The width “d” across which to cut the outer circumference of the first wafer 6a needs to be set to obtain a processed first wafer 6a having a radius “r-d” on the basis of the radius “r” of the second wafer 6b as a reference.

In order to set the width “d” appropriately, it is necessary to grasp the radius “r” of the second wafer 6b highly accurately. In the detection misalignment acquiring step S80 described above, the positional relation between the to-be-measured-wafer holding mechanism 14 and the detector 16 is grasped by measuring the distance between the rotary table 14a and the detector 16, after which joint misalignment of the detector 16 from a fixed position due to temperature changes is detected, and then the radius of the second wafer 6b is accurately calculated in view of the detected misalignment. On the basis of the accurately calculated radius of the second wafer 6b, it is possible to set an appropriate value as the width “d” and to cut the first wafer 6a to the desired radius “r-d.”

The laminated wafer 56 with the processed outer circumference as indicated by the solid lines in FIGS. 9A and 9B is thus fabricated according to the process described above.

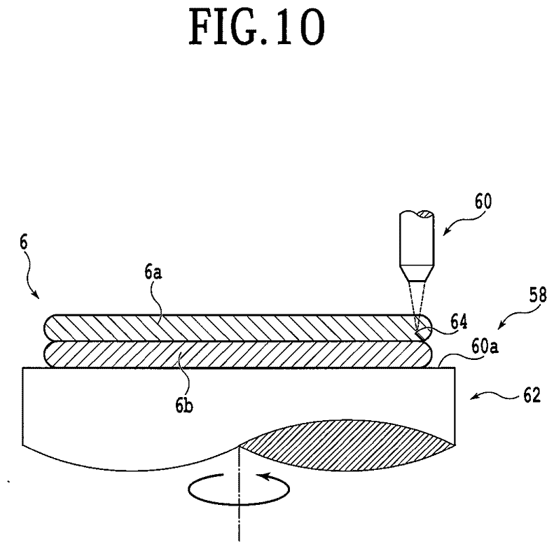

In the processing step S70, the laminated wafer 6 may be processed by other means than the cutting blade 28 described above. FIG. 10 schematically illustrates in cross section, partly in side elevation, another process of processing the laminated wafer 6 by way of example. The process illustrated in FIG. 10 forms a modified layer in the first wafer 6a with a laser beam.

A laser processing apparatus 58 illustrated in FIG. 10 is used to form the modified layer in the first wafer 6a. The laser processing apparatus 58 includes a laser beam applying unit 60 for applying the laser beam to the laminated wafer 6 and a holding mechanism 62 for holding the laminated wafer 6.

The laser beam applying unit 60 refers to a mechanism for introducing and focusing a laser beam emitted from a laser oscillator, not depicted, with an optical system including optical elements such as a lens and a mirror, not depicted, for example, and applying the focused laser beam to the laminated wafer 6 held by the holding mechanism 62.

The holding mechanism 62 includes a chuck table, for example, for holding the laminated wafer 6 under suction. The holding mechanism 62 has an upper surface 62a acting as a holding surface for holding the laminated wafer 6 thereon. The upper surface 62a as the holding surface is supplied with a negative pressure from a suction source, not depicted, for attracting the laminated wafer 6 under suction to the upper surface 62a. The holding mechanism 62 has a lower portion coupled to a rotating mechanism, not depicted, for rotating the holding mechanism 62 about its vertical central axis.

For forming a modified layer in the first wafer 6a, the laminated wafer 6 is held on the holding surface 62a of the holding mechanism 62, and the laser beam from the laser oscillator that is hardly absorbable by the first wafer 6a, i.e., that has a wavelength transmittable through the first wafer 6a, is applied to the first wafer 6a. The laser beam is focused by a condensing lens provided in the laser beam applying unit 60 and is applied to the first wafer 6a while positioning its focused spot at a target position in the first wafer 6a.

As illustrated in FIG. 10, the laser beam applying unit 60 that is positioned above the holding mechanism 62 applies the laser beam to the outer circumference of the first wafer 6a that is positioned below the laser beam applying unit 60. At the same time that the laser beam is applied to the first wafer 6a, the holding mechanism 62 is rotated about its vertical central axis, so that the laser beam is applied in an annular pattern to the first wafer 6a.

The laser beam applied to the first wafer 6a forms an annular modified layer 64 in the first wafer 6a in the vicinity of the focused spot. The annular modified layer 64 is positioned radially outwardly of a central region of the first wafer 6a in which the devices are present and extends in surrounding relation to the central region.

The laser beam may be caused to branch off by an optical element such as a diffractive optical element (DOE) or a reflective liquid crystal on silicon (LCOS) element, for example, and then applied to the first wafer 6a.

The modified layer refers to a region whose density, refractive index, mechanical strength, and other physical properties are different from the surrounding base material. Specifically, the modified layer refers to a region that has been subjected to a melting process, a region that has cracks, a region that suffers dielectric breakdown, a region whose refractive index is different from other regions, or a region where the above regions exist together. For example, the modified layer has a lower mechanical strength than the surrounding regions.

In this manner, a laminated wafer with a processed outer circumference is fabricated by processing the outer circumference of the first wafer 6a of the laminated wafer 6 to form a modified layer therein with a laser beam.

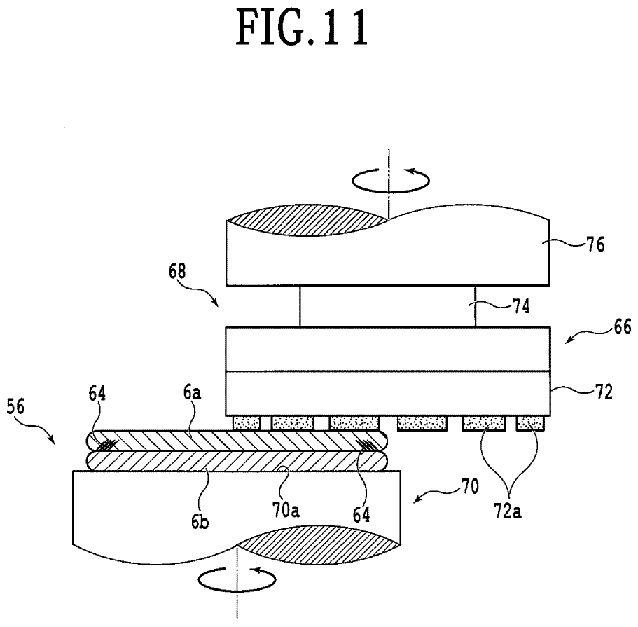

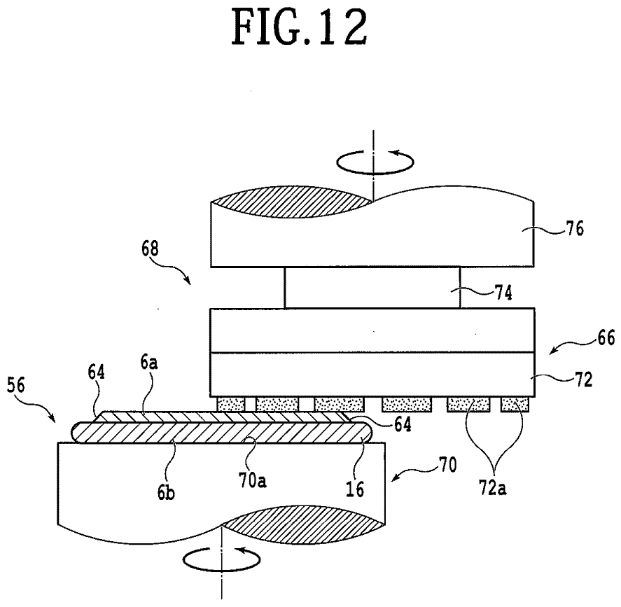

Then, the laminated wafer with the processed outer circumference is thinned down by grinding. FIGS. 11 and 12 schematically illustrate respective stages of the other process of processing the laminated wafer illustrated in FIG. 10 by way of example. FIGS. 11 and 12 schematically illustrate the manner in which a laminated wafer 56 with a processed outer circumference is ground.

In a case where the outer circumference of the first wafer 6a is processed by being thinned down after the modified layer 64 has been formed in the first wafer 6a as illustrated in FIGS. 10 through 12, the laminated wafer 6 in which the devices are constructed in the surface of the first wafer 6a that is joined to the second wafer 6b, i.e., the surface of the first wafer 6a with the devices constructed therein is joined to the second wafer 6b, i.e., the laminated wafer 56 with the processed outer circumference, is used as a workpiece.

For grinding the laminated wafer 6, a grinding apparatus 66 illustrated in FIGS. 10 and 11 is used to grind the first wafer 6a from its reverse side 4b that is exposed upwardly. The grinding apparatus 66 includes a grinding unit 68 and a holding mechanism 70.

The grinding unit 68 includes a vertical spindle 74 having a lower end on which a grinding wheel 72 is mounted, and a housing 76 in which the spindle 74 is rotatably supported. The spindle 74 is of a cylindrical shape and rotatably housed in the housing 76 with its central axis extending vertically. The grinding wheel 72 is mounted on a wheel mount that is attached to the lower end of the spindle 74. The spindle 74 has an upper end coupled to a rotary actuator, not depicted, such as an electric motor, for example.

The grinding wheel 72 includes a disk-shaped component having a lower surface to which an annular array of grindstones 72a are secured along circumferential directions thereof. The grinding wheel 72 is mounted on the wheel mount on the lower end of the spindle 74 such that the lower surface of the grinding wheel 72 with the grindstones 72a secured thereto faces downwardly. When the rotary actuator coupled to the upper end of the spindle 74 is energized, it rotates the spindle 74 about its vertical central axis, rotating the grinding wheel 72 together with the grindstones 72a.

The holding mechanism 70 includes a chuck table, for example, for holding the laminated wafer 6 under suction. The holding mechanism 70 has an upper surface 70a acting as a holding surface for holding the laminated wafer 6 thereon. The upper surface 70a as the holding surface is supplied with a negative pressure from a suction source, not depicted, for attracting the laminated wafer 6 under suction to the upper surface 70a. The holding mechanism 70 has a lower portion coupled to a rotating mechanism, not depicted, for rotating the holding mechanism 70 about its vertical central axis.

A nozzle as a processing liquid supply unit, not depicted, is disposed near the holding surface 70a for supplying the laminated wafer 6 with a processing liquid such as water required to grind the laminated wafer 6. The processing liquid may alternatively be supplied through a fluid channel, not depicted, defined in the grinding unit 68.

For grinding the laminated wafer 6, as illustrated in FIG. 11, the laminated wafer 6 is held by the holding mechanism 70 such that the reverse side of the first wafer 6a faces upwardly toward the grinding unit 68 and the second wafer 6b is held in contact with the holding surface 70a.

With the spindle 74 positioned above the holding mechanism 70, the spindle 74 is rotated together with the grinding wheel 72 about its vertical central axis, and the holding mechanism 70 is rotated together with the laminated wafer 6 about its vertical central axis. The spindle 74 and the holding mechanism 70 are vertically moved relatively closer to each other to bring the grindstones 72a and the first wafer 6a into abrasive contact with each other, thereby grinding the first wafer 6a from the reverse side, i.e., the upper surface. While the first wafer 6a is being ground, the nozzle supplies water as the processing liquid to the first wafer 6a.

As the grinding of the first wafer 6a progresses, the reverse side thereof is gradually worn downwardly until it reaches the modified layer 64 formed in the first wafer 6a or cracks developed in the first wafer 6a from the modified layer 64. Then, as illustrated in FIG. 12, the region of the first wafer 6a that is positioned radially outwardly from the modified layer 64 is torn off and removed.

Instead of being ground by the grinding apparatus 66, for example, the first wafer 6a may alternatively be thinned down by being cut by a cutting apparatus, not depicted. The cutting apparatus includes a cutting unit and a holding mechanism, for example.

The cutting unit includes a vertical spindle having a lower end on which a cutting blade is mounted and a housing in which the spindle is rotatably supported. The cutting blade includes an annular base and an annular cutting edge attached to the annular base and extending along an outer circumferential portion of the annular base, for example.

The spindle is of a cylindrical shape and has an end to which a blade mounter with the cutting blade mounted thereon is attached and an opposite end coupled to a rotary actuator such as an electric motor, for example.

For cutting the first wafer 6a, the laminated wafer 6 is held by a holding surface of the holding mechanism such that the reverse side of the first wafer 6a faces upwardly toward the cutting unit. The cutting blade is rotated together with the spindle and cuts into the first wafer 6a from the reverse side thereof. While the cutting blade is cutting into the first wafer 6a, the cutting unit and the holding mechanism are relatively moved in a direction along the holding surface of the holding mechanism, thinning down the first wafer 6a from its reverse side.

As the first wafer 6a is progressively thinned down, the reverse side thereof gradually falls downwardly until it reaches the modified layer 64 formed in the first wafer 6a or cracks developed in the first wafer 6a from the modified layer 64. Then, the region of the first wafer 6a that is positioned radially outwardly from the modified layer 64 is torn off and removed.

In a case where device chips are to be manufactured from the laminated wafer 56 with the processed outer circumference, the processing step S70 is followed by the peeling step S90. In the peeling step S90, the first wafer 6a is peeled off from the second wafer 6b by applying ultrasonic waves to the laminated wafer 56, supplying a fluid such as water to the joined interference between the first and second wafers 6a and 6b, or applying external forces to the laminated wafer 56, for example.

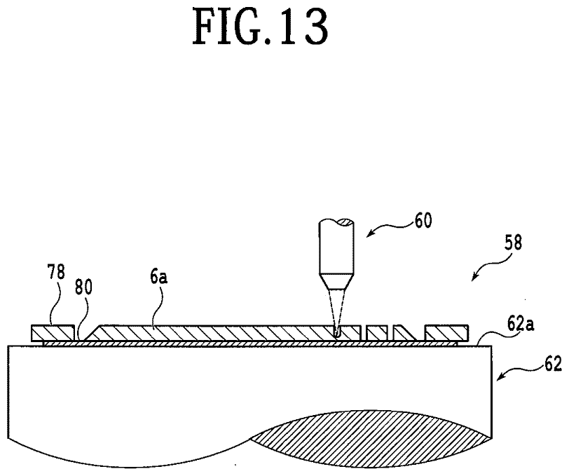

After the first wafer 6a has been peeled off from the second wafer 6b, the dividing step S100 is carried out to divide the first wafer 6a into device chips. FIG. 13 schematically illustrates, in cross section, partly in side elevation, the manner in which the first wafer 6a is divided by way of example.

The dividing step S100 can be carried out by the laser processing apparatus 58 including the laser beam applying unit 60 and the holding mechanism 62, which is used in the process of forming a modified layer in the first wafer 6a in the processing step S70 as illustrated in FIG. 10.

In the example illustrated here, after the peeling step S90, the first wafer 6a peeled off from the second wafer 6b is affixed to a tape 80 that has been affixed to an annular frame 78.

The frame 78 includes a plate-shaped annular component made of metal, for example, and has a central hole defined therein. The tape 80 that has an adhesive layer made of an adhesive on a surface thereof has been affixed to a lower surface of the frame 78 and is exposed upwardly through the central hole in the frame 78. The tape 80 includes a circular sheet of resin with the adhesive layer on a surface thereof and has an outer circumferential portion affixed to the frame 78. The face side of the first wafer 6a where the devices are constructed is affixed to a central portion of the tape 80.

In the dividing step S100, the laser beam applying unit 60 applies the laser beam to the first wafer 6a held by the holding mechanism 62 of the laser processing apparatus 58. The laser beam applied to the first wafer 6a has a wavelength absorbable by the material of the first wafer 6a. The wavelength of the laser beam applied to the first wafer 6a in the dividing step S100 may be different from the wavelength of the laser beam applied to the first wafer 6a in the process of forming a modified layer in the first wafer 6a in the processing step S70. In that case, another laser processing apparatus that is different from the laser processing apparatus used in the process of forming a modified layer in the first wafer 6a in the processing step S70 may be used. However, since the other laser processing apparatus shares structural details and appearance with the laser processing apparatus 58 illustrated in FIG. 10, the other laser processing apparatus will be described below with reference to FIG. 10 that is incorporated herein by way of reference.

While the laser beam is being applied to the first wafer 6a, the holding mechanism 62 and the laser beam applying unit 60 are relatively moved in a direction along the holding surface 62a of the holding mechanism 62, thereby abrading the first wafer 6a along projected dicing lines established thereon. The first wafer 6a is now divided into individual pieces as device chips.

In the dividing step S100, the laser beam applied to the first wafer 6a may form grooves in the first wafer 6a along the projected dicing lines by way of laser abrasion, after which the first wafer 6a may be divided into device chips along the grooves. Alternatively, the laser beam applied to the first wafer 6a may form modified layers in the first wafer 6a along the projected dicing lines, after which the first wafer 6a may be divided into device chips along the modified layers.

Further alternatively, the dividing step S100 may be carried out by a cutting apparatus that may be identical to the cutting apparatus used in the process of thinning down the first wafer 6a in the processing step S70, for example.

For cutting the first wafer 6a, the cutting blade that is rotating together with the spindle cuts into the first wafer 6a held by the holding mechanism. While the cutting blade is cutting into the first wafer 6a, the cutting unit and the holding mechanism are relatively moved in a direction along the holding surface of the holding mechanism, thereby dividing the first wafer 6a along the projected dicing lines into device chips. Alternatively, after the cutting blade has formed cut grooves in the first wafer 6a along the projected dicing lines by cutting into the first wafer 6a, the first wafer 6a may be divided into device chips by a process of applying an external force to the first wafer 6a, for example.

The method of manufacturing a laminated wafer with a processed outer circumference and the method of manufacturing device chips described above may further include other steps than the steps described above, e.g., a polishing step, a cleaning step, an ultraviolet ray applying step, and/or a film growing step.

According to the present embodiment, the to-be-measured-wafer holding mechanism 14 for holding the laminated wafer 6 when it is measured for joint misalignment and the to-be-processed-wafer holding mechanism 10 for holding the laminated wafer 6 while it is being processed have been described as separate mechanisms. However, the to-be-measured-wafer holding mechanism 14 and the to-be-processed-wafer holding mechanism 10 may be combined and provided as a single holding mechanism. In other words, the to-be-measured-wafer holding mechanism 14 as the first holding mechanism and the to-be-processed-wafer holding mechanism 10 as the second holding mechanism may be a same holding mechanism.

Such a single holding mechanism operates as follows. While the laminated wafer is being held by the holding mechanism as the chuck table, joint misalignment is measured by the detector disposed sideways of the holding mechanism, and the laminated wafer held by the holding mechanism is cut on the basis of the data acquired from the measured joint misalignment. The image capturing device for capturing an image of the laminated wafer from above the holding mechanism may be dispensed with, and the position of the first wafer may be measured by the detector disposed sideways of the holding mechanism.

The workpiece to be processed, the processing apparatus, and the other structural details described above may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing a laminated wafer with a processed outer circumference from a laminated wafer including a first wafer and a second wafer that are each plate-shaped and have respective surfaces joined to each other, by processing an outer circumference of the first wafer, the method comprising:
acquiring a value of joint misalignment between the first wafer and the second wafer by measuring a position of the outer circumference of the first wafer and a position of an outer circumference of the second wafer;
holding the second wafer of the laminated wafer on a holding surface of a holding mechanism;
acquiring a position of the first wafer with respect to the holding mechanism while the laminated wafer is being held by the holding mechanism;
acquiring a position of the second wafer with respect to the holding mechanism on a basis of the acquired value of the joint misalignment and the acquired position of the first wafer; and
processing the outer circumference of the first wafer on a basis of the acquired position of the second wafer as a reference.

2. The method according to claim 1, which uses a processing apparatus including
the holding mechanism that is rotatable about a rotational axis extending transversely to the holding surface, and
a cutting blade for cutting into the laminated wafer held by the holding mechanism,
the method further comprising:
acquiring a value of misalignment between a position of a rotational axis of the holding mechanism and a position of a center of the second wafer held by the holding mechanism, wherein
the outer circumference of the first wafer is cut by
rotating the holding mechanism together with the laminated wafer held by the holding mechanism, and
cutting the outer circumference of the first wafer while adjusting a position of the cutting blade with respect to the holding mechanism depending on an angle of the holding mechanism on a basis of the value of misalignment between the position of the rotational axis of the holding mechanism and the position of the center of the second wafer held by the holding mechanism.

3. A processing apparatus for processing a laminated wafer including a first wafer and a second wafer that are each plate-shaped and have respective surfaces joined to each other, the processing apparatus comprising:
a first holding mechanism for holding a target;
a detector for detecting a position of an outer circumference of the target held by the first holding mechanism at a position spaced radially outwardly from the target;
a cutting blade for cutting into the target held by a second holding mechanism; and
a controller for adjusting a relative positional relation between the second holding mechanism and the cutting blade.

4. The processing apparatus according to claim 3, wherein the first holding mechanism and the second holding mechanism are the same holding mechanism.

5. A method of manufacturing device chips using the method of manufacturing a laminated wafer with a processed outer circumference from a laminated wafer including a first wafer and a second wafer that are each plate-shaped and have respective surfaces joined to each other, by processing an outer circumference of the first wafer, the method including
acquiring a value of joint misalignment between the first wafer and the second wafer by measuring a position of the outer circumference of the first wafer and a position of an outer circumference of the second wafer,
holding the second wafer of the laminated wafer on a holding surface of a holding mechanism,
acquiring a position of the first wafer with respect to the holding mechanism while the laminated wafer is being held by the holding mechanism,
acquiring a position of the second wafer with respect to the holding mechanism on a basis of the acquired value of the joint misalignment and the acquired position of the first wafer, and
processing the outer circumference of the first wafer on a basis of the acquired position of the second wafer as a reference, the method further comprising:
after the outer circumference of the first wafer has been processed, dividing the first wafer into device chips.
